(19) United States
(12) Patent Application Publication
(10) Pub. No.: US 2024/0353495 A1
(43) Pub. Date: Oct. 24, 2024

(54) METHOD FOR MONITORING A CHARGING LEVEL OF A BATTERY, AND ASSOCIATED STORAGE SYSTEM

(71) Applicant: SAFRAN ELECTRICAL & POWER, BLAGNAC (FR)

(72) Inventor: Marie SAYEGH, MOISSY CRAMAYEL (FR)

(21) Appl. No.: 18/687,663

(22) PCT Filed: Aug. 26, 2022
(86) PCT No.: PCT/FR2022/051614

§ 371 Date: Feb. 28, 2024

(30) Foreign Application Priority Data
Sep. 3, 2021 (FR) 2109250

(51) Int. Cl. G01R 31/367; G01R 31/36; G01R 31/3832

(52) U.S. Cl. CPC G01R 31/367; G01R 31/3647; G01R 31/3648; G01R 31/3833

(57) ABSTRACT

A method including calculating a total electrical charge accumulated in a battery at the current time by Coulomb counting on the basis of a total electrical charge accumulated in the battery at a previous time and on the basis of a current supplied by the battery, calculating a stored charge state, equal to the total accumulated electrical charge divided by a maximum total charge, calculating an available electrical charge on the basis of a difference between the total electrical charge and a non-extractible electrical charge which cannot be extracted from the battery because of its temperature, calculating an available charge state, equal to the available electrical charge divided by a maximum available charge.

### TECHNICAL FIELD

The technical field is that of monitoring and management of electric batteries, in particular batteries on board a vehicle, especially an aircraft.

### TECHNOLOGICAL BACKGROUND

Major development forces are underway to develop and enhance electric or hybrid propulsion aircraft, because of their environmental and ecological benefits. In such aircraft, management and monitoring of electric batteries are particularly important, given their role in the propulsion of the aircraft, especially as the conditions in which these batteries are used can make it difficult to restore the electrical charge stored therein (sometimes extreme operating temperatures, high current demands).

The management and monitoring of electrical batteries is also important in an aircraft propelled by turbojet engines, even if these batteries are not propulsion batteries, because they provide electrical power to the instruments and on-board electronics (as well as some actuators), which are needed to pilot the aircraft.

The electrical charge stored in a battery at a given instant is often represented by a quantity called the State Of Charge (SOC) or charge level. The state of charge SOC, often expressed as a percentage of the total capacity of the battery, is generally equal to the ratio between, on the one hand, a charge accumulated in the battery at the instant considered and, on the other hand, a maximum or nominal charge Qₘₐₓ that can be stored in this battery (i.e.: accumulated charge divided by the total capacity of the battery).

One known technique to evaluate the state of charge (SOC) of a battery is to measure the Open Circuit Voltage (OCV), Uₒ, across the battery, as well as the battery temperature (T). Its state of charge SOC is then determined using a chart, characteristic of the battery, which relates the state of charge SOC to these two quantities, Uₒ and T. In general, however, this technique can only be used when the battery is

not delivering current.

When the battery is delivering current, its state of charge can be tracked by Coulomb counting, by measuring the current i it delivers and integrating it over time to deduce the electrical charge delivered by the battery. The state of charge SOC is then determined in accordance with formula F1 below:

$$SOC = {SOC}_{0} - ( \int i \times dt ) / {Q}_{max} \qquad ( F1 )$$

where SOCₒ is an initial state of charge, determined as explained above on the basis of the open-circuit voltage Uₒ (at an initial instant for which the current delivered i is zero, or at least low).

One drawback of this method is that a slight bias or error in the calibration of the current sensor can end up leading to a significant error in the estimated state of charge SOC, as this error is accumulated over time, by integration.

Above all, the charge level SOC estimated in this way is not directly representative of the electrical charge that is actually available, that is that can actually be delivered by the battery at the instant considered. Indeed, in this formula, the electrical charge taken into account is the electrical charge stored in the battery, present (physically) in it. However, the electrical charge that can actually be delivered may be lower than this stored charge: according to the operating conditions of the battery (especially temperature and discharge current), some of the charge stored in the battery cannot be extracted therefrom.

This drawback is easy to understand when considering a situation in which the battery has been discharged to a SOC of 30%, for example. Subsequently, when the battery is not discharging or is discharging very little, its temperature abruptly falls. The value of the SOC, estimated according to formula F1, will then still be 50%, when in fact the battery is in a situation where it can hardly deliver any current (because of its low temperature).

To overcome these drawbacks, it has been provided, for example in document U.S. Pat. No. 6,534,954, to determine an available state of charge, representative of a charge that can actually be delivered under the conditions considered, this determination being carried out on the basis of:
a measurement of the current i delivered (measured taken into account by Coulomb counting),
and also a measurement of the voltage U across the battery (not necessarily an open-circuit voltage) and its temperature T,
these measurements being taken into account by means of a state observer, for example of the Kalman filter type (the current being taken into account during the prediction, that is course, step, while the voltage and temperature are taken into account, via a battery operating model, during the updating, that is filter resetting step).

However, calculations required to estimate available state of charge of the battery in this way are very significant (as is often the case when a Kalman filter is resorted to). In addition, setting of the filter parameters (the value of the feedback gains, or “Kalman gains”, for example, which are recalculated at each time step) is generally fairly empirical, and does not necessarily ensure an optimum estimate of the state of charge.

### SUMMARY

In this context, a method is provided for monitoring a charge level of an electrical storage battery, the method comprising steps of:
measuring an electrical current delivered by the battery,
measuring a battery temperature,
calculating, by an electronic processing and control system, a total electrical charge accumulated in the battery at a current instant, by Coulomb counting, as a function of a total electrical charge accumulated in the battery at a previous instant and as a function of the electrical current measured,
calculating a stored state of charge, equal to the total electrical charge accumulated in the battery at the current instant, divided by a maximum total charge that can be accumulated in the battery, calculating an available electrical charge as a function of a difference between (for example equal to the difference between)
   the total electrical charge accumulated in the battery at the current instant, and
   a non-extractable electrical charge which cannot be extracted from the battery given its temperature, the non-extractable electrical charge being determined as a function of at least said measured temperature, from operating characteristics of the battery stored in a memory of the electronic processing and control system,
calculating an available state of charge, equal to the available electrical charge, divided by a maximum available charge, the maximum available charge being equal to the difference between, on the one hand, a maximum achievable charge, that can be accumulated in the battery at most when it is charged to said temperature and, on the other hand, said non-extractable electrical charge.

The maximum total charge that can be accumulated in the battery, mentioned above, is for example the maximum charge that can be accumulated in the battery for optimal charging conditions, or for nominal charging conditions.

The maximum achievable charge is also determined, like the non-extractable charge, as a function of at least said measured temperature, from said operating characteristics of the battery.

In this method, instead of directly determining the course of an available charge level, taking account both of the electrical charge delivered and the battery operating conditions in a coupled manner, the following are separately calculated:
the course in the electrical charge present in the battery (total electrical charge accumulated in the battery), and
the influence of current operating conditions (especially temperature) on the electrical charge that can actually be restored (available charge).

This decoupling between the course of the electrical charge on the one hand, and taking account of the conditions of restoring this charge on the other hand, clearly simplifies calculations compared with the estimate based on a Kalman filter set forth above. Indeed, each of these two operations is inexpensive per se, in terms of calculation.

In fact, Coulomb counting alone requires very little calculation. And as for the influence of operating conditions on the electrical charge that can actually be restored, this can be estimated, for example, by virtue of a mapping table or a numerical formula relating the electrical charge actually stored to the electrical charge available, for different operating conditions, this relation having been determined, for example, during prior tests of the restored charge (described below). The calculation in question is therefore also inexpensive.

This way of estimating the available state of charge also has the advantage of being robust (again, by virtue of the decoupling in question). Indeed, during this method, the piece of data relating to the total electrical charge accumulated in the battery is kept as it is, which piece of data has a high degree of reliability in terms of charge tracking (since it is the electrical charge actually physically present in the battery). In the Kalman filter-based method set forth in the preamble, however, this piece of information is progressively lost, as the stored electrical charge is corrected, in a way continuously hybridised with the conditions under which the charge is restored (this drawback is also encountered in other conventional methods, without a Kalman filter, wherein the variation in charge by Coulomb counting and the influence of operating conditions are taken into account simultaneously, in a sort of coupled manner).

Furthermore, both states of charge determined during this method, namely the stored state of charge and the available state of charge, both provide very useful and complementary information. It is therefore particularly interesting to estimate these two quantities this way, rather than just one.

Indeed, the stored state of charge provides information about the charge present in the battery, independently of the operating conditions. On its own, this state of charge is not sufficient to monitor (and drive) the battery, since the charge actually available may be much lower than that indicated by this state of charge, depending on the operating conditions at the instant considered (this situation corresponds, for example, to point A in FIG. 4). However, this indicator remains useful precisely because it avoids variability due to possible changes in operating conditions (for a user, seeing a state of charge vary when the battery is not being used can be a source of confusion, and it is therefore useful to have a “stable” indicator such as this stored state of charge).

As for the available state of charge, it provides an easily interpretable indication, representative of the charge immediately available, given the current operating conditions. However, as the operating conditions are likely to change (or be adjusted, by driving the battery), it is also useful to have a piece of information on the charge (absolute, as it were) stored in the battery, independently of these operating conditions (which information is provided by the stored state of charge).

By way of example, the combined use of the available state of charge and the stored state of charge makes it possible to detect a situation in which the immediately available charge is low, while the stored charge is in fact relatively high. In this situation, it may be more adapted to order battery heating (and/or a redistribution of the total current to provide, between different aircraft batteries), rather than initiating a descent phase of the aircraft equipped with this battery.

In this application, the terms “electrical charge” and “charge” are employed interchangeably.

The calculation steps set forth above are executed by the electronic processing and control system, which has the structure of a calculator, or computer.

Further to the characteristics set forth above, the method set forth above may have one or more of the following optional characteristics, considered individually or according to any technically contemplatable combinations:
the non-extractable electric charge is further determined as a function of the measured electric current, the non-extractable electric charge being an electric charge which cannot be extracted from the battery when it has a temperature equal to said measured temperature and delivers a current equal to said electric current measured;
the maximum achievable charge is determined as a function of said temperature and the electric current measured, the maximum achievable charge being an electric charge that can be accumulated in the battery at most when the battery is charged at a temperature equal to the measured temperature and with a charge current equal, in absolute value, to the electric current measured;
the method comprises a preliminary step of characterising the battery, during which at least some of the operating characteristics of the battery are determined by carrying out charge and discharge tests on a test battery of the same model as said battery, or on a test cell of such a test battery;
during the preliminary characterisation step, to determine the non-extractable electrical charge at a given test temperature, the following operations are performed on the test battery or on the test cell:
   Charging the battery or test cell, then
   At said test temperature, firstly discharging the battery or test cell until an operating threshold voltage is reached across the battery or test cell, then
   Modifying temperature of the battery or test cell to bring it up to optimum operating temperature, then
   At the optimum operating temperature, secondly discharging the battery or of the test cell, by counting the electrical charge which is delivered until the voltage across the battery or of the test cell reaches said operating threshold voltage, the electrical charge which cannot be extracted at said test temperature being determined from the delivered electrical charge counted during this second discharge;
the operating characteristics of the battery comprise a mapping table at least mapping battery temperature values to corresponding non-extractable electrical charge values and thus to corresponding maximum achievable charge values;
the operating characteristics of the battery comprise a first numerical calculation formula relating at least the non-extractable electrical charge to the temperature of the battery, and a second numerical calculation formula relating the maximum achievable electrical charge to the temperature of the battery, the first and second formulae each being parameterised by coefficients whose values are characteristic of said battery;
during the method, a man-machine interface indicates said available state of charge and said stored state of charge;
the battery and the electronic processing and control system equip a vehicle, for example an aircraft, and the electronic processing and control system:
   determines a piloting recommendation as a function of the available state of charge and the stored state of charge, and
   orders said man-machine interface to indicate said piloting recommendation and/or orders one or more actuators of the vehicle to pilot the vehicle in accordance with said piloting recommendation;
when a predetermined condition relating to both the stored charge state and the available charge state is met, the electronic processing and control system orders:
   a modification in battery temperature, and/or
   a modification in a distribution, between several batteries of a set of batteries to which said battery belongs, of a total electric current to be delivered.

The present technology also relates to an electricity storage system comprising an electrical storage battery, a temperature sensor arranged to measure a temperature of the battery, a current sensor measuring the electric current delivered by the battery, and an electronic processing and control system including at least a processor and a memory, the electronic processing and control system being configured to perform the following steps of:
calculating a total electrical charge accumulated in the battery at a current instant, by Coulomb counting, as a function of a total electrical charge accumulated in the battery at a previous instant and as a function of an electrical current measured by the current sensor,
calculating a stored state of charge, equal to the total electrical charge accumulated in the battery at the current instant, divided by a maximum total charge that can be accumulated in the battery,
calculating an available electrical charge based on a difference between,
   the total electrical charge accumulated in the battery at the current instant, and
   a non-extractable electric charge which cannot be extracted from the battery given its temperature, the non-extractable electric charge being determined as a function of at least the temperature measured by said temperature sensor, and from operating characteristics of the battery stored in the memory of the electronic processing and control system;
calculating an available state of charge equal to said available electrical charge divided by a maximum available charge, the maximum available charge being equal to the difference between, on the one hand, a maximum achievable charge that can be accumulated in the battery at most when it is charged to said temperature and, on the other hand, said non-extractable electrical charge.

The electronic processing and control system is configured to acquire the value of the temperature in question, measured by the temperature sensor, and to acquire the value of the electric current i measured by the current sensor.

The additional characteristics set forth above in terms of method can also be applied to the storage system just described.

The present technology also relates to a vehicle, in particular an aircraft, comprising such an electricity storage system.

The present technology and its different applications will be better understood upon reading the following description and upon examining the accompanying figures.

### BRIEF DESCRIPTION OF THE FIGURES

The figures are set forth by way of indicating and in no way limiting purposes.

FIG. 1 schematically represents an aircraft equipped with an electricity storage system based on the present technology.

FIG. 2 schematically represents steps in a method for monitoring an electric battery in the storage system of FIG. 2.

FIG. 3 schematically represents the course, as a function of temperature, of a non-extractable electrical charge and a maximum achievable charge, for the battery in question.

FIG. 4 represents the course of an available state of charge of this battery, as a function of a stored state of charge and temperature.

### DETAILED DESCRIPTION

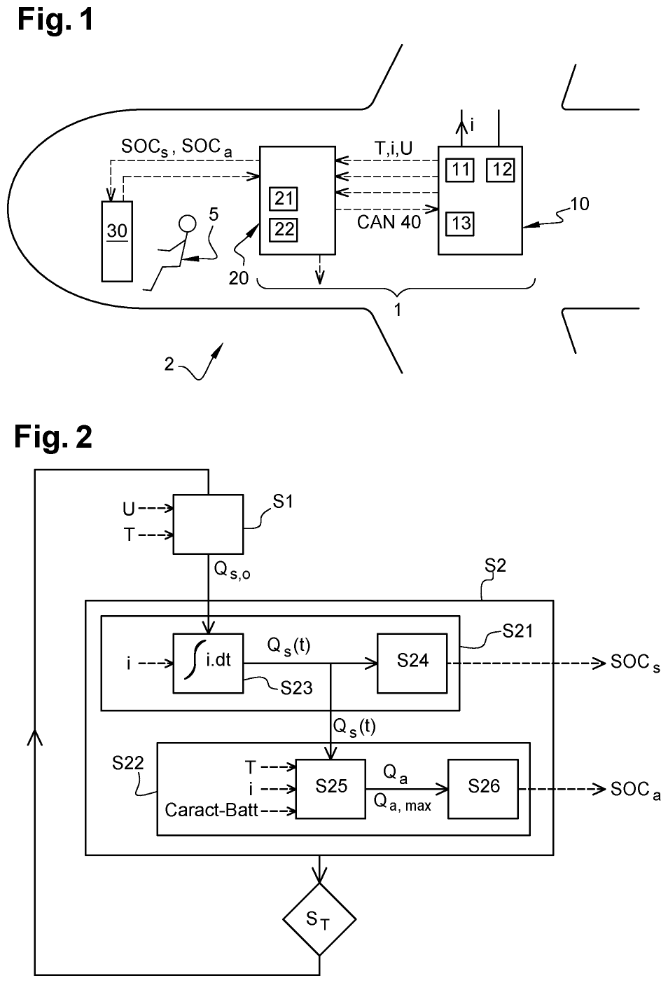

As indicated in the section entitled “summary”, the present technology relates to an electricity storage system, 1 (FIG. 1), and an associated method for monitoring a charge level (the more or less charged state, or, in other words, the more or less charged character) of an electrical storage battery 10 of this storage system (FIG. 2). During this method, the following are intended to be determined:
a stored state of charge SOCₛ (where index “s” stands for “stored”), directly determined from a total electrical charge Qₛ accumulated in the battery 10 (irrespective of the conditions under which the battery delivers current), and
an available state of charge SOCₐ (with index “a” stands for “available”), based on an available electrical charge Qₐ that can effectively be extracted from the battery 10, given the conditions under which the battery delivers current (temperature and current conditions especially).

The general structure of the storage system is described first. The method in question, and examples of the use of this particular pair of states of charge, are then set forth.

### Electricity Storage System

FIG. 1 schematically represents this storage system 1, which herein equips an aircraft 2, in this case a fixed-wing aircraft.

The storage system 1 comprises the electrical storage battery 10, for supplying electrical equipment in the aircraft. This equipment may be propulsion equipment, such as electric propfans, or piloting equipment, such as an electronic piloting unit or an aircraft attitude control actuator (for example an aileron control actuator, such as an electric jack).

Different types of battery technology are contemplatable for the battery 10, in particular relating to the basic material or set of materials from which the battery 10 is made (for example lead, or Nickel and Cadmium, or Lithium and Cobalt and Manganese). And different types of anode or cathode may be used (for example, if the battery 10 is a Lithium battery, it may be graphite or Lithium Titanate Oxide “LTO” anodes, and Lithium Ferro Phosphate “LFP” or Nickel-Manganese-Cobalt “NMC” Lithium Oxide cathodes, for example).

In addition, the battery 10 may, as shown here, comprise several electrochemical cells electrically connected with each other in series (to achieve a sufficiently high voltage) and/or in parallel (to achieve the required power levels). The battery 10 may also comprise several batteries, connected in series and/or in parallel, each battery gathering several cells.

The storage system 1 also comprises:
a current sensor 11, for measuring an electrical current i delivered by the battery; this current is the total electrical current delivered by the battery; it is positive when the battery delivers current, and negative when it is charging; the current sensor is, for example, a digital ammeter connected to the output of the battery (it may, for example, be a clamp ammeter with a Hall effect sensor, or a device for measuring voltage across a very low shunt resistance through which the current i passes);
a temperature sensor 12 (made, for example, from thermocouples or thermistors) to measure the temperature T of the battery 10; and
a voltage sensor 13 (of the digital voltmeter type), to measure the voltage, U, across the output terminals of the battery 10.

These sensors, which provide information about the operating conditions of the battery 10, can be integrated into the battery 10 or mounted externally to it.

The storage system 1 also includes an electronic processing and control system 20. The electronic processing and control system 20 has especially the function of monitoring the state of charge of the battery 10, by determining the states of charge SOCₛ and SOCₐ mentioned above.

The processing and control system 20 has the structure of a calculator (in this case an on-board calculator), or, stated differently, a computer. It comprises an electronic circuit (in one or more parts) equipped with at least one non-volatile memory 22, and a processor 21 for executing logic operations. It may also include one or more other memories (not represented), such as random access memory (RAM) or another type, and one or more other processors.

Here, the processing and control system 20 comprises several different Electronic Control Units (ECUs). Each of these electronic control units (i.e. each of these modules) is a calculator configured to monitor, control and/or pilot one or more members of the aircraft 2. The processing and control system 20 especially comprises an electronic control unit of the BMU type (Battery Management Unit) type for monitoring the battery 10 and, optionally, for driving it. It also includes an electronic unit configured to drive a man-machine interface 30. The man-machine interface 30, which comprises displays and command members, enables a pilot 5 of the aircraft to monitor the flight and operating parameters of the aircraft, and also enables him/her to drive the propulsion and steering members of the aircraft. The processing and control system 20 also comprises an electronic unit configured to command one or more of the aircraft's propulsion or steering components, in order to modify its flight parameters. These different electronic control units are connected to each other so that they can exchange data (and possibly instructions). Each of the electronic control units in question may be in the form of an electronic circuit comprising, for example, a programmable microcircuit (e.g. of the FPGA—Field Programmable Gate Array—type).

Alternatively, the processing and control system considered could only comprise the BMU mentioned above. Further alternatively, instead of comprising several separate electronic units, the processing and control system could take the form of a single common electronic control unit, executing the different functions mentioned above.

The sensors 11, 12, 13 are connected to the processing and control system 20 so as to be able to transmit data representative of the current i, the temperature T and the voltage U measured to this system. These data are transmitted from one to the other, for example, via a data bus 40, a CAN (Controller Area Network)-type bus.

The processing and control system 20 is configured, for example programmed (by virtue of instructions stored in memory 22, or by configuring a reconfigurable logic gate circuit) to execute the steps of the monitoring method which are represented in FIG. 2.

### Method for Monitoring the More or Less Charged State of the Battery

This method comprises determining the states of charge of the battery SOCₛ and SOCₐ mentioned above. This determination is carried out by the processing and control system 20, which is configured to acquire the current, temperature and voltage values measured by the sensors 11, 12, 13, and to calculate the states of charge SOCₛ and SOCₐ on this basis (FIG. 2).

The way in which these two states of charge are determined is described firstly. Different possible uses for this pair of states of charge (uses that form part of the method in question) are then set forth.

The method in question may also include a preliminary step of characterising the battery 10 (a step not represented in the figures), during which operating characteristics Caract_Batt of the battery 10 are determined, by carrying out charge and discharge tests on a test battery of the same model as said battery 10, or on a test cell of such a test battery. This preliminary step will be described secondly.

During this method, the total electrical charge Qₛ stored in the battery 10 is determined by Coulomb counting, using the electrical current i measured by the current sensor 13.

For this, an initial charge Q_{s,o}, accumulated in the battery 10 at an initialisation instant tₒ, is first determined during an initialisation step S1 (see FIG. 2). During this step, the initial charge Q_{s,o} is calculated as a function of:
the voltage U across the battery 10, preferably measured at no charge (i.e. at a time when the current i delivered is zero), and
of its temperature T,
and on the basis of a battery operating model, the characteristics of which (relation between stored charge, voltage and temperature) are stored in memory 22, for example.

This operating model can be determined beforehand, for example, by making measurements in the preliminary step mentioned above. Determining the initial charge Q_{s,o} in itself is not the core of the innovation set forth here, and will therefore not be described further.

The method then includes a step S2 of calculating the states of charge SOCₛ and SOCₐ. This step comprises:
a step S21, which comprises calculating the total accumulated charge, Qₛ (in a counting step S23) and calculating the stored charge state SOCₛ (step S24), and
a step S22, which comprises calculating the available charge Qₐ (in a step S25) and the available charge state SOCₐ (in a step S26).

In the counting step S23, the total charge Qₛ is calculated, by Coulomb counting, on the basis of the current i measured, and with the initial charge Q_{s,o} as the starting point. The total charge Qₛ is thus calculated in accordance with the following formula F2:

$${Q}_{s} = {Q}_{s , 0} - \int i \times dt \qquad ( F2 )$$

This calculation is carried out continuously, that is the value of the total charge Qₛ accumulated in the battery is updated at each new time step (on the basis of the current i measured at the time step considered). Stated differently, the current i is continuously integrated over time t. This gives the total charge Qₛ (t) accumulated in the battery at each time step (at each instant t).

The stored state of charge SOCₛ is calculated, at each time step, by dividing the total charge Qₛ by a maximum total charge Q_{s,max} that can be accumulated in the battery 10:

$${SOC}_{s} = {Q}_{s} / {Q}_{s , max} \qquad ( F3 )$$

The maximum total charge Q_{s,max} is the total charge that can be stored in the battery under favourable, or even optimal, charging conditions for the battery in terms of operation. These charge conditions may correspond to the nominal operating conditions recommended for this battery 10 by its manufacturer, in terms of temperature and current delivered or received (operating conditions for which the battery has been designed).

Here, the maximum total charge Q_{s,max} is more precisely equal to the maximum charge that can be accumulated in the electric battery (starting from a situation in which the battery is completely discharged) when its temperature is equal to an optimum operating temperature Tₒₚₜ (the temperature at which the total charge that can be accumulated is greatest). In terms of current, charging the battery to the maximum total charge Q_{s,max} is made in two steps. The first step is made with a constant charge current iₒₚₜ (optimum charge current) until the operating voltage limit is reached. Then, a second charging step is carried out at constant voltage, the voltage across the battery being kept equal to the limit voltage reached previously, while continuing to charge the battery until the charge current becomes very low, or even zero.

In practice, the optimum operating temperature Tₒₚₜ may correspond to a moderate temperature (neither too low nor too high), for example between 20 and 50 degrees Celsius in the case of a lithium battery, or it may possibly correspond to a slightly higher temperature, depending on the type of battery technology employed. As for the optimum charge current iₒₚₜ, this may correspond to a current of reduced intensity, for which a full charge of the battery takes at least 5 hours, for example.

The maximum total charge Q_{s,max} may, for example, be equal to a nominal charge capacity specified for this battery by its manufacturer when operating conditions are optimal (this nominal capacity being indicated by the battery manufacturer, for example, among the different battery specifications).

In step S25, the processing and control system 20 determines the non-extractable electrical charge Q_{s,minlim}, accumulated in the battery 10 but which cannot be extracted from the battery given its temperature T and the current i delivered by the battery.

The non-extractable electrical charge Q_{s,minlim} is determined as a function of temperature T and current i, from the battery operating characteristics Caract_Batt stored in memory 22 of the processing and control system 20.

These operating characteristics Caract_Batt, which can take the form of a mapping table (of the LUT type), or the form of numerical calculation formulae, relating values for temperature and current delivered with values for non-extractable electrical charge Q_{s,minlim} corresponding to these temperature and current conditions.

The operating characteristics Caract_Batt also relate the temperature and current values in question to maximum achievable charge Q_{s,maxlim} values. The maximum achievable charge Q_{s,maxlim} is the charge up to which the battery 10 can be charged when it is at temperature T and when it is charged at an electrical charge current which, in absolute value, is equal to i.

The operating characteristics Caract_Batt can be obtained, in a preliminary test step (described below), by mapping the expected performance for the battery under different operating conditions.

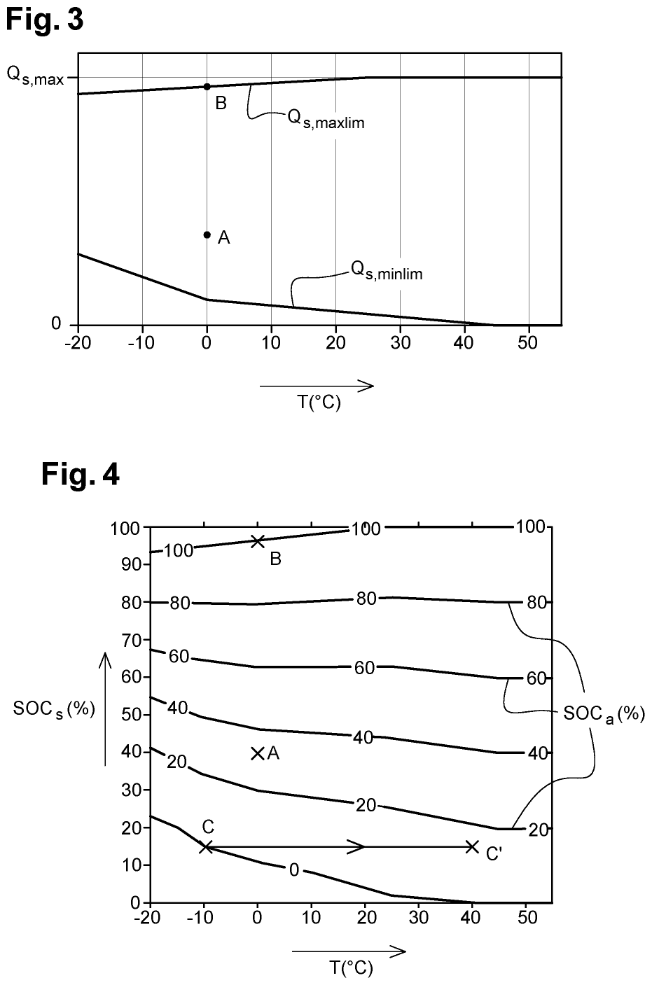

FIG. 3 represents the course of the maximum achievable charge Q_{s,maxlim} and the non-extractable charge Q_{s,minlim} (expressed in Amperes.hours), as a function of the operating temperature T (expressed in degrees Celsius), for an example of a battery that can be employed in the energy storage system of FIG. 1, and for a typical current value i (in other words, this is an intersection, at constant i, of the mapping of Q_{s,minlim}(T,i) and Q_{s,maxlim}(T,i)). In this case, it is a moderate value of current.

For this example, the non-extractable charge Q_{s,minlim} decreases (which is favourable, in terms of operation) as the temperature T increases, and becomes almost zero when the temperature T is greater than or equal to about 40 degrees Celsius. On the other hand, at temperatures below about 0 degrees Celsius, the non-extractable charge Q_{s,minlim} takes large values that can reach up to a quarter of the battery's total capacity (around −20 degrees Celsius), which clearly shows the importance of taking this non-extractable charge into account.

As for the maximum achievable charge Q_{s,maxlim}, up to about 25 degrees Celsius, it slightly increases with temperature, reaching a value close to the maximum total charge Q_{s,max} of the battery (total battery capacity), and then remains constant.

Once the non-extractable electrical charge Q_{s,minlim} is determined, the processing and control system 20 calculates the available electrical charge Qₐ as being equal to the difference between the total charge Qₛ stored in the battery, and the non-extractable electrical charge Q_{s,minlim}, which cannot be extracted from the battery under the conditions considered:

$${Q}_{a} = {Q}_{s} - {Q}_{s , minlim} \qquad ( F4 )$$

In step S25, the processing and control system 20 also determines the maximum achievable charge Q_{s,maxlim} corresponding to the operating conditions considered (on the basis of the operating characteristics Carract_Batt), and calculates a maximum available charge Q_{a,max}, equal to the difference between the maximum achievable charge Q_{s,maxlim} and the non-extractable electrical charge Q_{s,minlim}:

$${Q}_{a , max} = {Q}_{s , maxlim} - {Q}_{s , minlim} \qquad ( F5 )$$

Then, in step S26, the processing and control system 20 calculates the available state of charge SOCₐ by calculating the ratio of the available charge Qₐ to the maximum available charge Q_{a,max}:

$${SOC}_{a} = {Q}_{a} / {Q}_{a , max} \qquad ( F6 )$$

As explained in the part entitled “summary”, thus decoupling the course of the stored electrical charge Qₛ, present in the battery, and the influence of the current operating conditions on the available electrical charge Qₐ which can actually be restored, makes it possible to simplify calculations considerably, and leads to a reliable estimate of the available charge.

In addition, the two estimated states of charge, SOCₛ and SOCₐ, both provide useful and complementary information about the electrical charge that can be recovered.

FIG. 4 schematically represents values of the available state of charge SOCₐ corresponding to different values of the stored state of charge SOCₛ, for different values of temperature T. On this graph, the value indicated at a given point on the graph (in the form of level lines) is the value of the available state of charge SOCₐ for the temperature indicated on the abscissa, and for the stored state of charge SOCₛ indicated on the ordinate.

As can be seen in this figure, the value of the available state of charge SOCₐ is often significantly different from the value of the stored state of charge SOCₛ, illustrating the complementary nature of these two parameters.

By way of example, for point A represented in FIG. 4 (and FIG. 3), for which T=0° C., there is SOCₛ=about 40%, whereas the available SOC SOCₐ is in fact only 30%. This illustrates that the stored state of charge SOCₛ on its own does not provide sufficient information to monitor state of charge of the battery.

In the situation corresponding to point B, where T=0° C., on the other hand, there is SOCₐ=100%, whereas in fact an additional electrical charge could still be accumulated in the battery (see FIG. 3), as additionally indicated by the stored state of charge SOCₛ (which is then about 95%).

And in the situation corresponding to point C, for which T =-10° C., there is SOCₐ=0% whereas in fact a non-zero electrical charge is stored in the battery (SOCₛ=about 15%), but is not available. In such a situation, in view of the values of SOCₐ and SOCₛ, it may be worthwhile commanding heating of the battery to increase its temperature (for example up to point C′, for which T=40° C., SOCₛ remaining equal to 15%, while the available state of charge switches from 0% to approximately 12%).

These different examples clearly show the benefits of knowing both the stored state of charge and the available state of charge.

Finally, as illustrated in FIG. 2, this method provides for reinitialising the values of the states of charge SOCₐ and SOCₛ, for example at regular intervals, in order to limit influence of any bias or error in measuring the current i (which, if accumulated over time, would end up distorting the estimation by Coulomb counting).

For this, when a reinitialising condition is verified (which condition is tested in step S_{T}), execution of step S2 is stopped and the method resumes by executing initialisation step S1 again (and then step S2 again). As mentioned above, in step S1, the charge contained in the battery is directly estimated on the basis of the open circuit voltage Uₒ across the battery (and taking account of the battery temperature T).

This reinitialising condition may relate to a time elapsed since the last instant of battery use: when this time exceeds a given threshold time (threshold duration of between 15 minutes and 3 hours, for example), initialisation step S1 is executed again. By the last instant of battery use, it is meant the last instant for which a substantial current has been delivered (or received) by the battery, the current delivered then being zero or very low, for example below a threshold representative of a measurement error for the current i. Optionally, the processing and control system can also be configured to allow this reinitialisation to be triggered manually by an operator (in addition to the regular interval reinitialisation mentioned above). As an alternative or in addition, the reinitialise condition considered could also correspond to the detection of an anomaly in the estimate of one of the states of charge SOCₐ and SOCₛ.

During this method, the value of the available state of charge SOCₐ is indicated by the man-machine interface 30 (the processing and control system 20 orders this interface to indicate this value), for example by means of a display screen for displaying data or images representative of this state of charge, or by means of an analogue indicator, for example a pointer indicator. The value of the stored state of charge SOCₛ can also, as here, be indicated by the man-machine interface 30. These values are continuously updated, each time a new state of charge is evaluated.

Furthermore, during the method, the processing and control system 20 regularly tests whether a predetermined condition, relating to both the stored state of charge SOCₛ and the available state of charge SOCₐ, indicates a low available state of charge (for example less than 20%, or even 10 or 5%) while the stored state of charge is relatively high (for example greater than 20 or 30%). When this condition is met, the processing and control system 20 can, for example, order a change in the temperature of the battery 10, by ordering a battery heating system to increase its temperature (if it is low, with respect to the optimum operating temperature Tₒₚₜ), or possibly by ordering a battery cooling system to lower its temperature (if it is high, with respect to the optimum operating temperature Tₒₚₜ).

If the storage system 1 comprises several electric batteries (for example one for left wing thrusters and another for right wing thrusters), the processing and control system 20 can also, when the condition in question is detected (i.e.: low SOCₐ and relatively high SOCₛ), order a modification in the distribution, between these different batteries, of a total electrical current to be delivered, in order to reduce intensity of the current i delivered by the battery 10 itself (in order to finally be able to extract a greater electrical charge from the battery 10).

During this method, the electronic processing and drive system 20 can also determine, on the basis of the state of charge values SOCₐ and SOCₛ, that a change in the flight parameters of the aircraft is desirable.

For example, if the available state of charge SOCₐ is low (e.g. less than 20%) while the stored state of charge SOCₛ is fairly high (e.g. greater than 30 or 40%), the processing and control system 20 can recommend a change to one or more of the aircraft's flight parameters, in order to reduce the intensity of the current delivered, so that a greater electrical charge can finally be extracted from the battery 10.

When the available state of charge SOCₐ and the stored state of charge SOCₛ both have low values (for example less than 10%), the processing and control system 20 can recommend initiating a descent phase of the aircraft, so that it can land before the battery 10 is completely discharged.

In either case, the piloting recommendation can be indicated to the aircraft pilot 5 via the man-machine interface 30. The processing and control system 20 can also directly command one or more of the aircraft's actuators (for example its thrusters, or cylinders actuating the elevators) to directly implement the piloting recommendation in question.

The method in question also comprises a preliminary characterisation step (not represented) during which the operating characteristics Caract_Batt of the battery 10 are determined by carrying out charge and discharge tests on a test battery of the same model as this battery 10, or on a test cell of such a test battery.

By the same model, it is meant a battery:
made from the same basic material or set of materials as the battery 10 (for example lead, or lithium, or nickel and cadmium, or even zinc and manganese),
using the same type of anode and cathode; for example, if battery 10 is a lithium battery with graphite anodes and lithium ferro phosphate “LFP” cathodes, this will also be the case for the test battery or test cell (and similarly if battery 10 is a lithium battery with Lithium Titanate “LTO” anodes and Nickel-Manganese-Lithium-Cobalt “NMC” Oxide cathodes, for example),
and dimensioned in the same way as the battery 10, or a cell in this battery (same electrode areas, same cell volume).

This could be a battery, or a battery cell, supplied by the manufacturer of battery 10, and which the manufacturer indicates that it is of the same model (additionally, the test battery could be battery 10 itself).

During this preliminary characterisation step, to determine the non-extractable electrical charge Q_{s,minlim} at a given test temperature, the following operations are carried out on the test battery or on the test cell:
charging the battery or test cell, and then
at said test temperature T_{T}, and for a given discharge current i_{d}, firstly discharging the battery or test cell until an operating threshold voltage is reached across the battery or test cell, and then
modifying temperature of the battery or test cell to bring it up to the optimum operating temperature Tₒₚₜ mentioned above, and then
at the optimum operating temperature Tₒₚₜ, and for the optimum discharge current iₒₚₜ, secondly discharging the battery or of the test cell, by counting (by Coulomb counting) an electrical charge Qr which is delivered until a voltage across the battery or of the test cell reaches said operating threshold voltage, the non-extractable electrical charge Q_{s,minlim} at said test temperature T_{T}, and for the discharge id mentioned above, being determined from the delivered electrical charge Qᵣ counted during this second discharge.

When the test is carried out directly on a test battery of the same capacity as the battery 10 (and not just on a test cell), the non-extractable electrical charge Q_{s,minlim} at said test temperature T_{T}, and for the discharge i_{d} is determined as being equal to the delivered electrical charge Qᵣ during this second discharge (since this charge is the residual charge, not having been extracted from the battery during the first discharge at the temperature T_{T}).

When the test is carried out on a test cell, of the same model as one of the cells of the battery 10, the non-extractable electrical charge Q_{s,minlim} at said test temperature T_{T}, and for the discharge id can for example be determined as being equal to the delivered electrical charge Qᵣ during the second discharge, multiplied by the number of cells of the battery 10 (or, possibly, on the basis of a more complete electrical modelling of the arrangement of cells forming the battery 10).

The operating threshold voltage, below which the battery stops being discharged, may be a voltage set by the conditions of use of the battery 10. For example, in the case of an electrical battery designed to deliver a voltage of 12 V, to supply a number of electrical appliances (designed to operate at 12 V), this threshold voltage may be set to 11.5 V, or at 11 V, slightly below the intended operating voltage.

The operating threshold voltage could also correspond to a threshold below which further discharging of the battery could damage the battery (since, for some types of battery, total, complete discharging of the battery can lead to premature ageing of the battery).

All the operations described above, which make it possible to determine non-extractable electrical charge Q_{s,minlim}, are executed several times, for several values of the test temperature T_{T}, and for several values of the discharge current i_{d}, to obtain a map as a function of temperature and current.

The maximum achievable charge Q_{s,maxlim} can also be determined during this preliminary characterisation step, by counting (by Coulomb counting), at the test temperature, and for a charge current equal, in absolute value, to id, the maximum charge that can be accumulated in the test battery or test cell. This charge is calculated from a situation where the battery or test cell is considered to be fully discharged. To fully discharge the battery (or at least to discharge it to a situation where it is considered empty), it is discharged at the optimum operating temperature Tₒₚₜ, and at current iₒₚₜ, until the voltage thereacross reaches the operating threshold voltage mentioned above.

Different alternatives can be brought to the method and storage system just set forth, in addition to those already mentioned.

Thus, the non-extractable electrical charge Q_{s,minlim} and the maximum achievable charge Q_{s,maxlim}, could be determined, in step S25, only as a function of the battery temperature, T, instead of being determined by taking account of both this temperature and the current delivered.

On the contrary, other parameters likely to influence these charges Q_{s,minlim} and Q_{s,maxlim} could be taken into account, in addition to the temperature T and the current i (in particular during step S25). Thus, a State Of Health (SOH), representative of a greater or lesser degree of ageing of the battery 10, could be taken into account to estimate these charges, which are involved in estimating the available state of charge SOCₐ.

Moreover, this method can be used to monitor a set of several batteries. By way of illustration, in the case of two batteries B1 and B2, the method can executed out in a similar way (same way of calculating the charges Qₛ, Qₐ, and Q_{a,max}, for each of both batteries), but by averaging the charges (for both batteries), or by taking, between both batteries, the minimum or maximum value of the charge considered, according to usage requirements, before calculating the overall states of charge.

Thus, for example, for two batteries connected in series, in the event of a discharge, an overall SOCₐ and an overall SOCₛ will be determined for the set of two batteries, equal respectively to the smaller of both SOCₐ of both batteries (“individual” SOCₐ), and to the smaller of both SOCₛ (“individual” SOCₛ) of both batteries (because it is the least charged battery which will limit the operation, during a discharge). Similarly, for two batteries connected in series, in the event of charging, an overall SOCₐ and an overall SOCₛ will be determined, for the set of two batteries, equal respectively to the greater of both SOCₐ of both batteries, and the greater of both SOCₛ of both batteries (because it is the most charged battery which will limit the charging operation).

Finally, the different operations carried out during this method could be gathered in steps, or organised differently, with respect to what has been set forth above. Thus, the charges Qₐ, Q_{a,max} and the available state of charge SOCₐ could be calculated in a single step, rather than in both steps S25 and S26.

1. A method for monitoring a charge level of an electrical storage battery, the method comprising:
measuring an electric current delivered by the battery,
measuring a temperature of the battery,
calculating, by an electronic processing and control system, a total electrical charge accumulated in the battery at a current instant, by Coulomb counting, as a function of a total electrical charge accumulated in the battery at a previous instant and as a function of the electrical current measured,
calculating a stored state of charge, equal to the total electrical charge accumulated in the battery at the current instant, divided by a maximum total charge that can be stored in the battery,
calculating an available electrical charge as a function of a difference between,
the total electrical charge accumulated in the battery at the current instant, and
a non-extractable electrical charge, which cannot be extracted from the battery given its temperature, the non-extractable electrical charge being determined as a function of at least said measured temperature, from operating characteristics of the battery stored in a memory of the electronic processing and control system,
calculating an available state of charge, equal to the available electrical charge, divided by a maximum available charge, the maximum available charge being equal to the difference between a maximum achievable charge, which can be accumulated at most in the battery when it is charged at said temperature, and said non-extractable electrical charge.

2. The method according to claim 1, wherein:
the non-extractable electric charge is further determined as a function of the electric current measured, the non-extractable electric charge being an electric charge which cannot be extracted from the battery when it has a temperature equal to said temperature measured and delivers a current equal to said electric current measured, and wherein
the maximum achievable charge is determined as a function of said temperature and the electrical current measured, the maximum achievable charge being an electrical charge that can be accumulated at most in the battery when the battery is charged at a temperature equal to the temperature measured and with a charge current equal, in absolute value, to the electrical current measured.

3. The method according claim 1, further comprising a preliminary step of characterising the battery, during which at least some of the operating characteristics of the battery are determined by carrying out charge and discharge tests on a test battery of the same model as said battery, or on a test cell of such a test battery.

4. The method according to claim 3, wherein, during the preliminary characterisation step, in order to determine the non-extractable electrical charge at a given test temperature, the following operations are carried out on the test battery or on the test cell:
charging the battery or test cell, and then
at said test temperature, firstly discharging the battery or test cell until an electrical operating threshold voltage is reached across the battery or test cell, and then
modifying the temperature of the battery or test cell to bring it to the optimum operating temperature, and then
at the optimum operating temperature, secondly discharging the battery or test cell, by counting the electrical charge which is delivered until the voltage across the battery or test cell reaches said operating threshold voltage, the non-extractable electrical charge at said test temperature being determined from the delivered electrical charge counted during this second discharge.

5. The method according to claim 1, wherein the operating characteristics of the battery comprise a mapping table mapping at least temperature values of the battery to corresponding non-extractable electrical charge values, as well as to corresponding maximum achievable charge values.

6. The method according to claim 1, wherein the operating characteristics of the battery comprise a first numerical calculation formula relating at least the non-extractable electrical charge to the temperature of the battery, and a second numerical calculation formula relating the maximum achievable electrical charge to the temperature of the battery, the first and second formulae each being parameterised by coefficients whose values are characteristic of said battery (10).

7. The method according to claim 1, during which a man-machine interface indicates said available state of charge and said stored state of charge.

8. The method according to claim 7, wherein the battery and the electronic processing and control system equip a vehicle, and wherein the electronic processing and control system:
determines a piloting recommendation as a function of the available state of charge and the stored state of charge, and
orders said man-machine interface to indicate said piloting recommendation and/or orders one or more vehicle actuators to pilot the vehicle in accordance with said piloting recommendation.

9. The method according to claim 1, wherein, when a predetermined condition relating both to the stored charge state and to the available charge state is met, the electronic processing and control system orders:
a modification in the temperature of the battery, and/or
a modification in a distribution, between several batteries of a set of batteries to which said battery belongs, of a total electric current to be delivered.

10. An electricity storage system comprising an electrical storage battery, a temperature sensor arranged to measure a temperature of the battery, a current sensor measuring the electrical current delivered by the battery, and an electronic processing and control system including at least a processor and a memory, the electronic processing and control system being configured to perform the following steps of:
calculating a total electrical charge accumulated in the battery at a current instant, by Coulomb counting, as a function of a total electrical charge accumulated in the battery at a previous instant and as a function of an electrical current measured by the current sensor,
calculating a stored state of charge, equal to the total electrical charge accumulated in the battery at the current instant, divided by a maximum total charge that can be accumulated in the battery,
calculating an available electrical charge as a function of the difference between,
the total electrical charge accumulated in the battery at the current instant, and
a non-extractable electrical charge, which cannot be extracted from the battery given its temperature, the non-extractable electrical charge being determined as a function of at least the temperature measured by said temperature sensor, and from operating characteristics of the battery stored in the memory of the electronic processing and control system,
calculating an available state of charge, equal to said available electrical charge, divided by a maximum available charge, the maximum available charge being equal to the difference between, on the one hand, a maximum achievable charge, which can be accumulated at most in the battery when it is charged at said temperature, and said non-extractable electrical charge.

11. A vehicle comprising an electricity storage system according to claim 10.

12. The method according to claim 8, wherein the vehicle is an aircraft.
